(19) United States
(12) Patent Application Publication
(10) Pub. No.: US 2010/0230671 A1
(43) Pub. Date: Sep. 16, 2010

(54) ZNO-BASED SEMICONDUCTOR AND ZNO-BASED SEMICONDUCTOR DEVICE

(76) Inventors: Ken Nakahara, Kyoto (JP); Shunsuke Akasaka, Kyoto (JP); Hiroyuki Yuji, Kyoto (JP); Masashi Kawasaki, Kyoto (JP); Akira Ohtomo, Miyagi (JP); Atsushi Tsukazaki, Miyagi (JP)

Correspondence Address: RABIN & Berdo, PC, 1101 14TH STREET, NW, SUITE 500, WASHINGTON, DC, 20005, US

(21) Appl. No.: 12/680,406

(22) PCT Filed: Sep. 26, 2008
(86) PCT No.: PCT/JP2008/067516

§ 371 Date: Mar. 26, 2010

(30) Foreign Application Priority Data
Sep. 27, 2007 (JP) 2007-251482

(51) Int. Cl. H01L 29/22

(52) U.S. Cl. 257/43; 257/E29.094

(57) ABSTRACT

Provided are a ZnO-based semiconductor capable of alleviating the self-compensation effect and of achieving easier conversion into p-type, and a ZnO-based semiconductor device. The ZnO-based semiconductor includes a nitrogen-doped Mg_{X}Zn_{1-X}O (0<X<1) crystalline material. The ZnO-based semiconductor is subjected to a photoluminescence measurement performed at an absolute temperature of 12 Kelvin, and thus a spectrum distribution curve is obtained. The ZnO-based semiconductor is formed so that a peak intensity of the distribution curve obtained at 3.3 eV or larger is stronger than a peak intensity of the distribution curve obtained at 2.7 eV or smaller. Consequently, the self-compensation effect can be reduced and the conversion into p-type becomes easier.

### TECHNICAL FIELD

The present invention relates to a ZnO-based semiconductor including a nitrogen-doped MgZnO crystalline material and a ZnO-based semiconductor device using the ZnO-based semiconductor.

### BACKGROUND ART

Studies have been made on application of devices made of a ZnO-based semiconductor, which is a type of oxide, to an ultraviolet LED used as a light source for illumination, backlight or the like, a high-speed electronic device, a surface acoustic wave device, and so forth. ZnO has drawn attention to its versatility, large light emission potential and the like. However, no significant development has been made on ZnO as a semiconductor device material. The largest obstacle is that p-type ZnO cannot be obtained because of difficulty in acceptor doping. Nevertheless, as demonstrated by Non-patent Documents 1 and 2, technological progress of recent years has made it possible to produce p-type ZnO, and has proven that light is emitted from the p-type ZnO. Accordingly, active research on ZnO is underway.

A proposal has been made on use of nitrogen as an acceptor for obtaining p-type ZnO. As disclosed in Non-patent Document 4, when ZnO is doped with nitrogen as an acceptor, the temperature of the substrate needs to be lowered because the efficiency of nitrogen doping heavily depends on a growth temperature. However, the lowering of the substrate temperature degrades crystallinity and forms a carrier compensation center that compensates the acceptor, and thus nitrogen is not activated (self-compensation effect). This makes the formation of a p-type ZnO layer, itself, extremely difficult.

With this taken into consideration, Non-patent Document 2 has disclosed a method of forming a p-type ZnO-based layer with a high carrier density by using a −C plane as a principal surface for growth and also using repeated temperature modulation (RTM) in which a growth temperature is alternately changed between 400° C. and 1000° C., the method thereby taking advantage of the temperature dependency of the efficiency of nitrogen doping.

However, this method involves the following problems. The continuous process of heating and cooling results in the alternate repetition of thermal expansion and contraction of the manufacturing machine. This imposes heavy burden on the manufacturing machine. For this reason, the manufacturing machine requires an extensive configuration, and periodic maintenance service at shorter intervals. Furthermore, the method requires the temperature to be accurately controlled because the doping amount is determined by a part of the process at the lower temperature. However, it is difficult to control the temperature so that the temperature will reach 400° C. and 1000° C. accurately in a short time period, and the reproducibility and stability of the doping thus become inadequate. Further, since the method uses a laser as a heating source, the method is not suitable for heating a large area. In addition, it is difficult to grow multiple semiconductor films, although the growth of multiple semiconductor films is needed to reduce device manufacturing costs.

### Non-patent Document 1: A. Tsukazaki et al., JJAP 44 (2005) L643

### Non-patent Document 2: A. Tsukazaki et al., Nature Material 4 (2005) 42

### Non-patent Document 3: M. Sumiya et al., Applied Surface Science 223 (2004) p. 206

### Non-patent Document 4: K. Nakahara et al, Journal of Crystal Growth 237-239 (2002) p. 503

### DISCLOSURE OF THE INVENTION

### Problems to be Solved by the Invention

On the other hand, as described in Non-patent Document 3, for example, it has been known that use of the +C plane of a ZnO substrate as the substrate for growth makes the doping of nitrogen easier. So, it is conceivable to use this method to solve the above-described problems. Use of the +C plane allows the doping of a certain amount of nitrogen to be secured even when the substrate temperature is increased, so that the above-described problems that would occur otherwise at the time of the RTM can be solved. Nevertheless, the self-compensation effect still remains. This allows no complete activation of nitrogen, making the conversion into the p-type still difficult.

An object of the present invention, made to solve the above-described problems, is providing a ZnO-based semiconductor capable of alleviating the self-compensation effect and of achieving easier conversion into p-type, and a ZnO-based semiconductor device.

To achieve the above object, the invention according to claim 1 is a ZnO-based semiconductor including a Mg_{X}Zn_{1-X}O (0<X<1) crystalline material doped with nitrogen, wherein, in a spectrum distribution curve obtained by a photoluminescence measurement performed on the ZnO-based semiconductor at an absolute temperature of 12 Kelvin, a peak intensity of the distribution curve obtained at 3.3 eV or larger is stronger than a peak intensity of the distribution curve obtained at 2.7 eV or smaller.

The invention according to claim 2 is a ZnO-based semiconductor including a Mg_{X}Zn_{1-X}O (0<X<1) crystalline material doped with nitrogen, wherein, in a spectrum distribution curve obtained by a photoluminescence measurement performed on the ZnO-based semiconductor at an absolute temperature of 12 Kelvin, an integral intensity of the distribution curve obtained at 3.3 eV or larger is stronger than an integral intensity of the distribution curve obtained at 2.7 eV or smaller.

The invention according to claim 3 is a ZnO-based semiconductor including a Mg_{X}Zn_{1-X}O (0<X<1) crystalline material doped with nitrogen, wherein, in a spectrum distribution curve obtained by a photoluminescence measurement performed on the ZnO-based semiconductor at an absolute temperature of 12 Kelvin, when an integral intensity of the distribution curve obtained at 3.3 eV or larger is denoted by A and an integral intensity of the distribution curve obtained at 2.7 eV or larger is denoted by B, (A/B)≧0.3 is satisfied.

The invention according to claim 4 is the ZnO-based semiconductor according to claim 3, wherein the (A/B) is equal to or larger than 0.4.

The invention according to claim 5 is a ZnO-based semiconductor including a Mg_{X}Zn_{1-X}O (0<X<1) crystalline material doped with nitrogen, wherein, in a spectrum distribution curve obtained by a photoluminescence measurement performed on the ZnO-based semiconductor at an absolute temperature of 12 Kelvin, when an integral intensity of the distribution curve obtained at 3.3 eV or larger is denoted by A and an integral intensity of the distribution curve obtained at 2.7 eV or larger is denoted by B, {A/(B−A)}≧1 is satisfied.

The invention according to claim 6 is the ZnO-based semiconductor according to any one of claims 3 to 5, wherein to calculate the integral intensity A, the distribution curve at 3.3 eV or larger is approximated by a Gaussian curve, and then the Gaussian curve is integrated.

The invention according to claim 7 is the ZnO-based semiconductor according to claim 6, wherein, if a plurality of luminescence peaks exist in the distribution curve at 3.3 eV or larger, the luminescence peaks are approximated respectively by Gaussian curves.

The invention according to claim 8 is the ZnO-based semiconductor according to any one of claims 1 to 7, wherein a concentration of the doped nitrogen is equal to or higher than 1×10¹⁸ cm⁻³.

The invention according to claim 9 is the ZnO-based semiconductor according to any one of claims 1 to 7, wherein: the crystalline material is a laminate formed by laminating a plurality of layers of Mg_{X}Zn_{1-X}O (0≦Xn<1) with Mg composition ratios that are different from one another; and at least one of the MgZnO films is doped with nitrogen at a concentration that is equal to or higher than 1×10¹⁸ cm⁻³.

The invention according to claim 10 is the ZnO-based semiconductor according to any one of claims 1 to 9, wherein: the crystalline material includes a MgZnO substrate in which a principal surface on a crystal-growth-direction side has a C plane, and a Mg_{Y}Zn_{1-Y}O (0<Y<1) film which is formed on the MgZnO substrate; and a projection axis, obtained by projecting a normal line to the principal surface onto a m-axis/c-axis plane of substrate crystal axes, is inclined in the m-axis direction within a range of 3°.

The invention according to claim 11 is the ZnO-based semiconductor according to any one of claims 1 to 10, wherein the crystalline material is formed by a crystal growth process performed at a growth temperature of 750° C. or higher.

The invention according to claim 12 is a ZnO-based semiconductor device comprising the ZnO-based semiconductor according to any one of claims 1 to 11.

### EFFECTS OF THE INVENTION

A ZnO-based thin film of the present invention is made of a nitrogen-doped MgₓZn₁₋ₓO (0<X<1) crystalline material, and is formed so that a photoluminescence measurement on the crystalline material would show that the DAP luminescence is weaker than the band edge luminescence. In addition, the ZnO-based thin film of the present invention is formed so that the peak in the DAP luminescence is smaller than the peak in the band edge luminescence. With this configuration, the self-compensation effect can be particularly reduced, which in turn activates nitrogen. Accordingly, it is possible to obtain a MgZnO thin film or a MgZnO laminate having a crystal quality that is high enough to use the MgZnO thin film or the MgZnO laminate as a p-type MgZnO. In addition, with the MgZnO thin film or the MgZnO laminate, it is possible to fabricate a high-performance ZnO-based semiconductor device.

### BRIEF DESCRIPTION OF THE DRAWINGS

FIG. 1 is related to MgZnO and ZnO and is a graph illustrating the relationship between the nitrogen concentration and the proportion of the band edge integral intensity to the total integral intensity.

FIG. 2 is related to MgZnO and ZnO and is a graph illustrating the relationship between the nitrogen concentration and the proportion of the band edge integral intensity to the DAP integral intensity.

FIG. 3 is graph illustrating the PL luminescence spectra of two different kinds of nitrogen-doped MgZnO and that of a nitrogen-doped ZnO.

FIG. 4 is graph illustrating the PL luminescence spectra of the two different kinds of nitrogen-doped MgZnO and that of the nitrogen-doped ZnO.

FIG. 5 is graph illustrating the PL luminescence spectra of the two different kinds of nitrogen-doped MgZnO and that of the nitrogen-doped ZnO.

FIG. 6 is a graph illustrating a comparison of the luminescence intensity of a case of using a nitrogen-doped MgZnO of the present invention with the luminescence intensity of a case of using a conventional, nitrogen-doped MgZnO.

FIG. 7 is a diagram illustrating the relationship of a line normal to a substrate principal surface with the substrate-crystal axes, which are c-axis, m-axis, and a-axis.

FIG. 8 is a diagram illustrating surfaces of a ZnO substrate of a case where a line Z normal to the substrate principal surface has an off angle only in the m-axis direction.

FIG. 9 is a diagram showing the surface of a film formed on a MgZnO substrate of a case where a line Z normal to the substrate principal surface has an off angle in the m-axis direction.

FIG. 10 is a diagram showing the surface of a film formed on a MgZnO substrate of a case where the line Z normal to the substrate principal surface has an off angle in the m-axis direction.

FIG. 11 is a graph illustrating the association between the surface flatness of a nitrogen-doped MgZnO thin film and the concentration of mixed-in Si.

FIG. 12 is a graph illustrating the association between the surface flatness of a nitrogen-doped MgZnO thin film and the concentration of mixed-in Si.

FIG. 13 is a graph illustrating the relationship between the temperature of the substrate and the arithmetic mean roughness of the surface of a ZnO-based thin film.

FIG. 14 is a graph illustrating the relationship between the temperature of the substrate and the root mean square roughness of the surface of the ZnO-based thin film.

FIG. 15 is a schematic diagram illustrating the mechanism of the DAP luminescence

FIG. 16 is a diagram illustrating an example of a ZnO-based semiconductor device made by use of a ZnO-based semiconductor of the present invention.

FIG. 17 is diagram illustrating basic structures of a case where a nitrogen-doped MgZnO layer is formed.

FIG. 18 is a diagram illustrating a general configuration of a PL measurement apparatus.

### DESCRIPTION OF SYMBOLS

1 ZnO substrate
2 Nitrogen-doped MgZnO layer

### BEST MODES FOR CARRYING OUT THE INVENTION

The present invention is based on our discovery of the fact that a nitrogen-added Mg_{X}Zn_{1-X}O (0<X<1) crystalline material has an effect to alleviate the self-compensation effect with compared to a crystalline material made solely of ZnO and is easier to be converted to p-type. In addition, we have found parameters that are needed for the conversion into p-type. Some examples of the above-mentioned Mg_{X}Zn_{1-X}O (0<X<1) crystalline material are a single layer of a MgZnO film, a multilayer laminate obtained by laminating plural layers of MgZnO films, and a laminate of a MgZnO substrate and a MgZnO film.

Most of the studies thus far made to convert a ZnO-based semiconductor into a p-type one are about the p-type ZnO. Typical examples of ZnO-based semiconductors are CdZnO and MgZnO. CdZnO, which is a narrow-gap material, has been rarely studied because of the poisonous nature of Cd. MgZnO, which is a wide-gap semiconductor, has not been considered as a target for the study of conversion into p-type for the following reasons, for example. Firstly, as a usually observable tendency of a wide-gap material, MgZnO has a larger energy for activating the accepter energy (i.e., it is more difficult to generate holes). In addition, it is difficult to increase the purity of MgZnO as it is often made from sintered bodies.

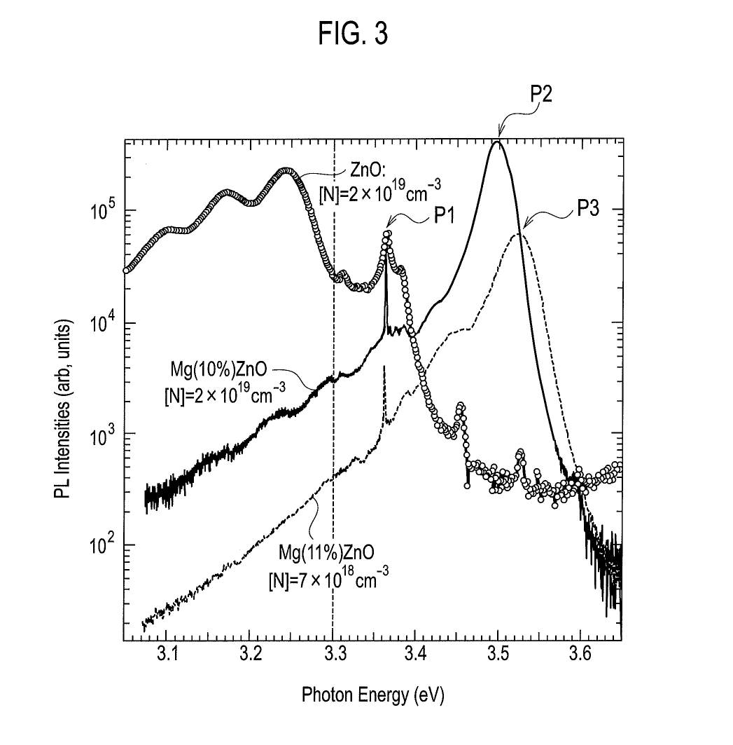

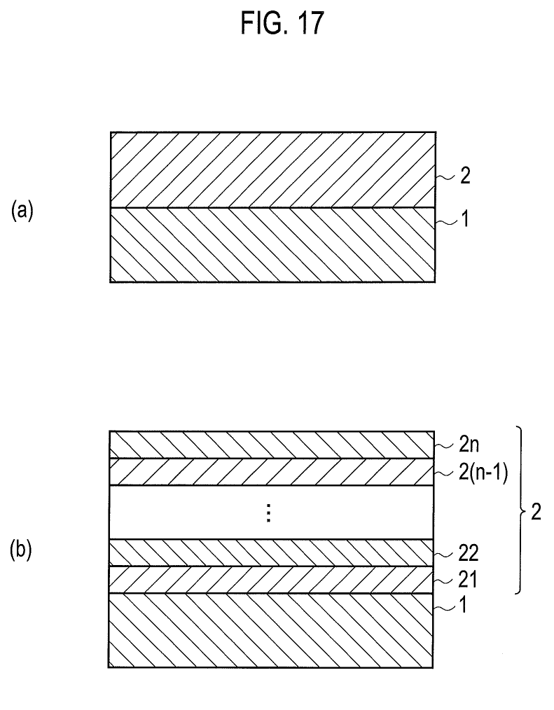

The inventors have discovered that MgZnO has an effect to reduce the self-compensation effect, which is a fact that has been unknown until then. FIG. 3 shows that MgZnO has a special effect to reduce or alleviate the self-compensation effect. FIG. 3 illustrates spectrum distributions obtained by photoluminescence (PL) measurement performed on a nitrogen-doped ZnO and two different kinds of nitrogen-doped MgZnO at an absolute temperature of 12 K (Kelvin). Each of the two different kinds of nitrogen-doped MgZnO used in the PL measurement is one formed through a crystal growth of a nitrogen-doped MgZnO layer 2 on a ZnO substrate 1, as FIG. 17(a) shows. The nitrogen-doped ZnO is one formed by making not through a crystal growth of a nitrogen-doped MgZnO layer 2 shown in FIG. 17(a) but the crystal growth of nitrogen-doped ZnO on the ZnO substrate 1.

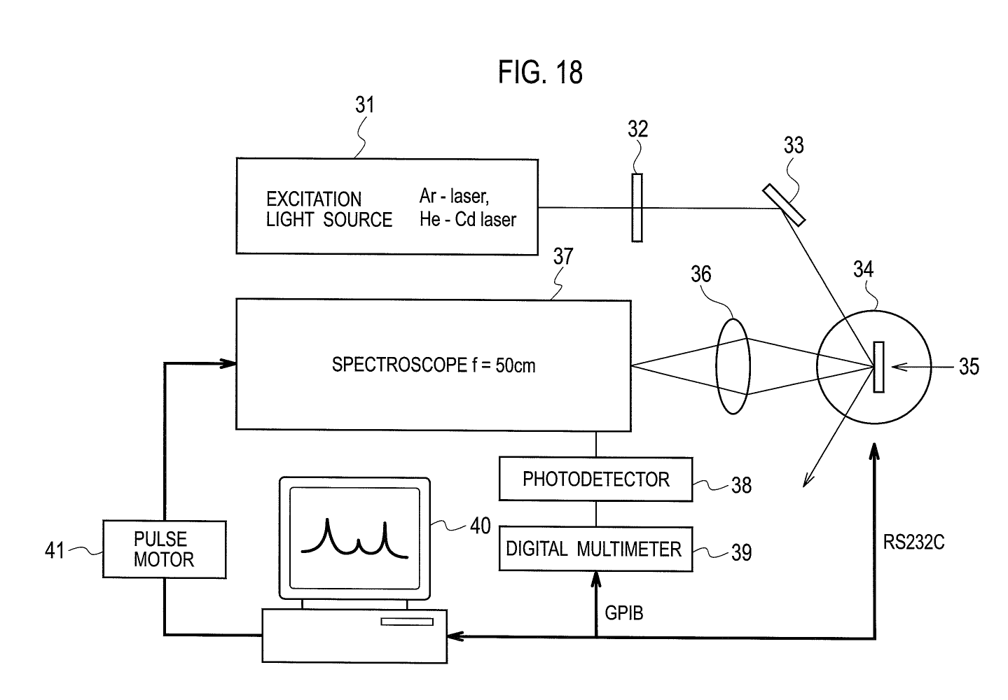

As a photoluminescence measurement apparatus, an apparatus whose configuration is shown in FIG. 18 was used. An Ar (argon) laser or a He—Cd (helium-cadmium) laser can be used as an excitation light source 31, and the photoluminescence measurement apparatus of the embodiment employed a He—Cd laser. The output of the He—Cd laser was within a range from 30 to 32 mW. The intensity of the excited light produced by the excitation light source 31 was approximately within a range from 1 to 10 W/cm². The output of the excited light immediately before a sample 35 was approximately within a range from 250 to 400 μW. The focal length of a spectroscope 37 was 50 cm. Diffraction gratings were formed in the spectroscope 37 at a pitch of 1200 gratings per millimeter. The blaze wavelength (the wavelength of maximum diffraction efficiency) was 330 nm. The diffracted light from the diffraction gratings had to be turned to focused light of a certain wavelength λ. To this end, a gear mechanism to rotate the diffraction gratings was provided, and a pulse motor 41 was provided to give the necessary rotation. A freezing apparatus 34 was capable of setting the freezing temperature within an absolute-temperature range from 10 to 200 K. A photodetector 38 included CCD detectors and had a 1024-ch configuration. The photodetector 38 was cooled by liquid nitrogen. The overall system including the spectroscope and the photodetector was what was known as SPECTRUM1 System (Manufactured by HORIBA JOVIN YVON).

A white-circle (∘) curve represents the measurement results of the nitrogen-doped ZnO whereas the other two curves represent the measurement results of the two different kinds of nitrogen-doped MgZnO. The measurement was performed under the condition that the concentration of the doped nitrogen for ZnO was set at 2×10¹⁹ cm⁻³, and, as to MgZnO, the concentration of doped nitrogen for Mg_{0.1}ZnO was set at 2×10¹⁹ cm⁻³ and the concentration of doped nitrogen for Mg_{0.11}ZnO was set at 7×10¹⁸ cm⁻³. The horizontal axis in FIG. 3 represents the photon energy (unit: eV) and the vertical axis represents the PL intensity. The unit for the vertical axis is an arbitrary unit that is usually used for PL measurement (i.e., logarithmic scale).

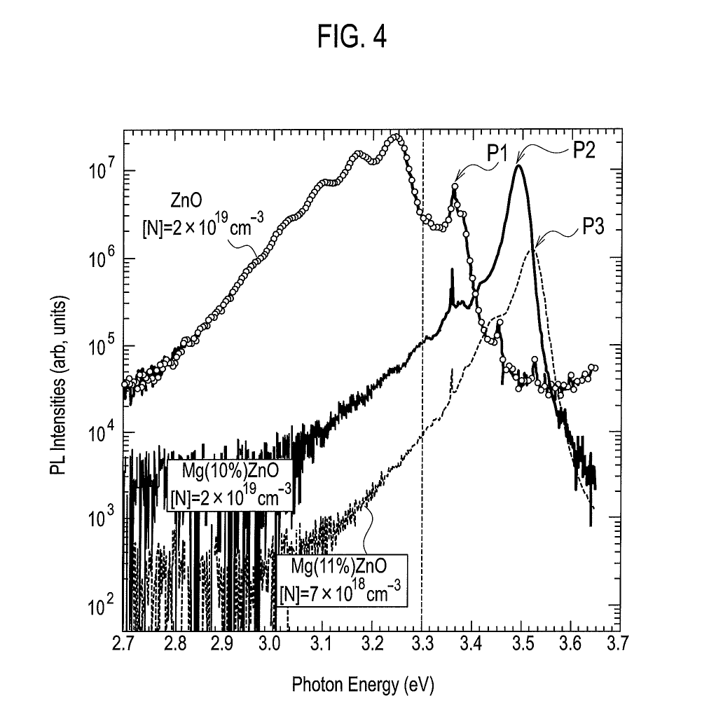

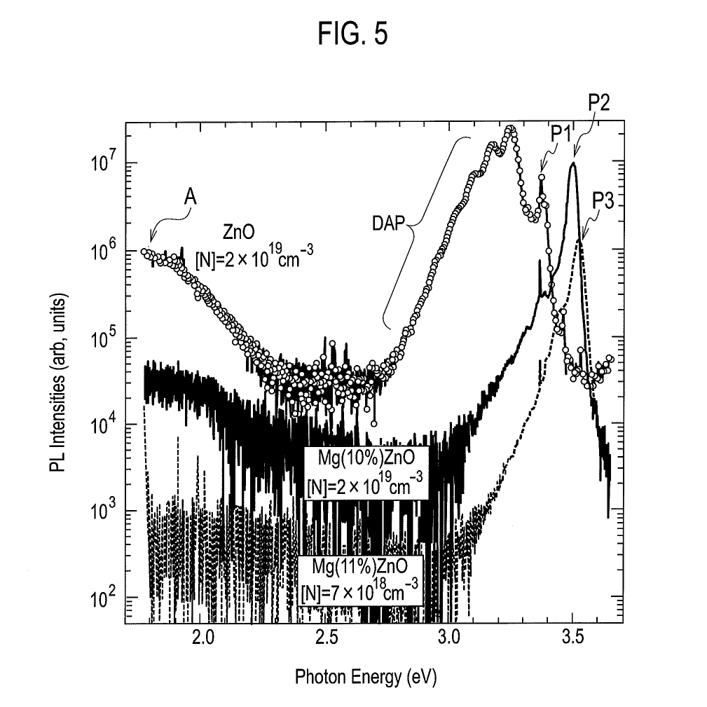

FIG. 5 shows a graph obtained by expanding the range of the horizontal scale of the graph in FIG. 3, which is from 3.05 to 3.65 eV, to a range from 2.1 to 3.7 eV. FIG. 4 is a graph obtained by expanding the horizontal scale of the graph in FIG. 3 to a range from 2.7 to 3.7 eV. The points P1, P2, P3 in each of FIGS. 3 to 5 represent the points where band edge luminescence occurred.

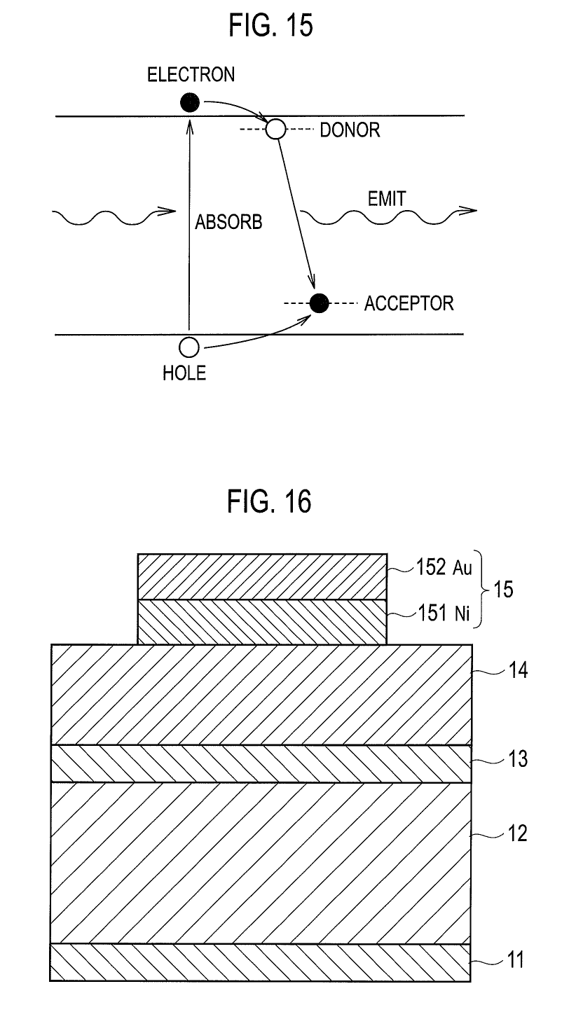

The point P1 in each of FIGS. 3 to 5 indicates the band edge luminescence peak energy of the nitrogen-doped ZnO. As has already been known, in the spectrum of the nitrogen-doped ZnO, a luminescence peak that is peculiar to the time of acceptor doping, known as donor-acceptor pair (DAP), appears at the lower energy side of the position P1. FIG. 15 is a schematic diagram illustrating the mechanism of the DAP luminescence. The position of the DAP luminescence is determined as follows.

When E_{DAP} is the energy of DAP luminescence, E_{G} is the minimum excitation energy, E_{D} is the donor level, E_{A} is the acceptor level, r_{DA} is the distance between the donor and the acceptor, ε₀ is the vacuum permittivity, εᵣ is the relative permittivity, e is the charges of electrons, h is the Planck's constant, and ω_{LO} is the LO (longitudinal-optical) phonon frequency, then

E_{DAP}=E_{G}−E_{D}−E_{A}+(e²/4πε₀εᵣr_{DA})−(mhω_{LO}/2π).

Here, m is an integer that is equal to or larger than zero.

The DAP luminescence peak position is determined by the equation above. So, given kinds of the donor and of the acceptor and their respective concentrations, the DAP luminescence peak position is determined.

If a line at 3.3 eV is the border to separate the region of band edge luminescence from the region of DAP luminescence, the region of DAP luminescence appears at the lower-energy side of the 3.3-eV line. In addition, as FIG. 5 shows, at a further lower-energy side of the DAP region, there is a region where as the energy becomes lower and lower, the PL intensity becomes higher and higher. A deep-level luminescence that is unique to the nitrogen doping can be observed. In an energy region that is close to A in FIG. 5, the intensity of the deep-level luminescence becomes significantly larger for the ZnO. The intensity of the deep-level luminescence for the MgZnO is more than one digit smaller than the corresponding intensity of the ZnO. This is a distinctive feature of MgZnO.

It is a well-known fact that as the density of the PL excitation light is raised, a blue shift of the luminescence peak of the DAP luminescence occurs. This phenomenon is means that is principally used for identifying the DAP luminescence. The solid-line curve and the dashed-line curve are of the wide-gap MgZnO. So, along the curves of the MgZnO, similar peaks to the band edge luminescence peak for the ZnO are observable, though slightly, at the same positions as that of the band edge luminescence peak P1 for the ZnO. This observation leads to easy understanding of the fact that in the case of the nitrogen-doped ZnO, the DAP luminescence is stronger than the ZnO band edge luminescence when the photon energy equals 3.3 eV or smaller. In the case of ZnO, the band edge luminescence becomes weaker and the DAP luminescence becomes stronger at the time of acceptor doping. Such a trend can be observed also in the cases of ZnSe and GaN, and is therefore quite normal. The fact is a reason why ZnO has been the commonly used material for the conversion into p-type.

The behavior of MgZnO is totally different as FIGS. 3 to 5 show. In each of FIGS. 3 to 5, the dashed line and the solid line represent the nitrogen-doped MgZnO of two different kinds. Both of the lines indicates that the luminescence in the vicinities of the band edge luminescence P2 and P3 is stronger than the DAP luminescence. In particular, the data shown by the solid line have quite weak DAP luminescence though the nitrogen concentration of this MgZnO is equal to the concentration of the ZnO curve. Such weak DAP luminescence is a noticeable characteristic of MgZnO, and can be considered as a phenomenon associated with the reduction in the self-compensation effect.

In addition, strong luminescence was observed when a nitrogen-doped MgZnO that has weak DAP luminescence and a ZnO substrate were bonded together. So, the observation showed that forming a nitrogen-doped MgZnO that has weak DAP luminescence is a parameter to achieve the conversion into p-type.

Next, the luminescence spectrum region of the PL measurement is divided into two regions, and the luminescence intensities of these two regions are compared with each other to quantify the parameter for the conversion into p-type. Firstly, on the basis of FIGS. 3 to 5, the border between the DAP luminescence region and the deep-level luminescence is set at 2.7 eV. In addition, as described above, the border between the DAP luminescence region and the band edge luminescence region is set at 3.3 eV.

As FIG. 17(a) shows, a nitrogen-doped MgZnO layer 2 was formed on a ZnO substrate 1 while the concentration of the doped nitrogen was varied from one device to another. Each device was subjected to the PL measurement under the above-described conditions. In addition, using the nitrogen-doped MgZnO as the p-type layer, an ultraviolet LED was fabricated as a ZnO-based semiconductor device. Luminescence of the ultraviolet LED was observed. The luminescence device had such a configuration as one shown in FIG. 16, for example. An undoped ZnO layer 13 and a nitrogen-doped p-type MgZnO layer 14 were formed on a ZnO substrate 12 in this order by crystal growth. Then, a p electrode 15 and an n electrode 11 were formed. As FIG. 16 shows, the p electrode 15 was formed as a multilayer metal film including a Au (gold) layer 152 and a Ni (nickel) layer 151. The n electrode 11 was made of In (indium). The nitrogen-doped MgZnO layer 14 corresponds to the nitrogen-doped MgZnO crystalline material of the present invention.

The nitrogen-doped MgZnO of different concentrations of doped nitrogen were subjected to a PL measurement to obtain spectrum distribution curves. Concerning each of the spectrum distribution curves, the PL intensity was integrated for an energy region starting from 3.3 eV until no PL luminescence can be observed. The value of integral is denoted by A. In this case, as can be seen from FIGS. 3 to 5, the integral interval was from 3.3 eV to 3.6 eV To calculate accurately the value of integral A, the band edge peaks P2, P3 and the like may be fitted with a Gaussian curve, and then the Gaussian curve may be integrated. As is well known, a Gaussian curve is expressed as:

f(x)={K/(2π)^{1/2}}×exp{−(x−m)²/2σ²}

where m is the average or the median value, σ is the standard deviation, and K is a constant.

Specifically, the values of m, σ, and K in the Gaussian curve are changed to calculate a curve that approximates most to the shape of the band edge luminescence peak, and the curve is used to obtain the value of integral A for a range from 3.3 eV to 3.6 eV. The fitting with a Gaussian curve is convenient particularly if there are plural band edge peaks. For example, if the nitrogen-doped MgZnO layer 2 is made of a laminate of MgZnO films having different concentrations of the doped nitrogen as in the case shown in FIG. 17(b), the measurement performed on the nitrogen-doped MgZnO layer 2 as a whole does not produce only one band edge peak but plural band edge peaks. If the laminate has two layers, a waveform thus produced resembles one formed, for example, by synthesizing P2 and P3 in FIG. 3 together.

To be more specific, as FIG. 17(b) shows, if n layers of nitrogen-doped MgZnO films 21 to 2n are formed one upon another, and if those n layers Mg_{X1}ZnO, Mg_{X2}ZnO, . . . , Mg_{Xn}ZnO (X1 to Xn are values which differ from one another and satisfy a relationship 0≦Xn≦1) are formed so as to have different nitrogen concentrations from one another, n band edge luminescence peaks exist in a mixed manner. In this case, each peak is firstly fitted (approximated) with a Gaussian curve, and the fitting curves thus obtained are denoted by f(z1), f(z2), . . . , and f(zn), respectively. Then, the band edge peak is expressed by the sum of the n Gaussian curves, that is, the band edge peak f(z)=f(z1)+f(z2)+ . . . +f(zn). The f(z) is integrated from 3.3 eV to 3.6 eV to obtain the value of integral A.

The value of integral A will be referred to as the band edge integral intensity, meaning the value of integral in the band edge luminescence region. Subsequently, the PL intensity is integrated for the energy region from 2.7 eV, which is the border between the deep-level luminescence region and the DAP luminescence region, to a region where no PL luminescence can be observed. The value of integral thus obtained will be denoted by B. In this case, as FIGS. 3 to 5 show, the integral interval is from 2.7 eV to 3.6 eV The value of integral B will be referred to as the total integral intensity because the value of integral B includes both the DAP luminescence region and the band edge luminescence region. In addition, the integral intensity for the DAP luminescence region C is defined as C+B−A. The value of integral C will be referred to as the DAP integral intensity.

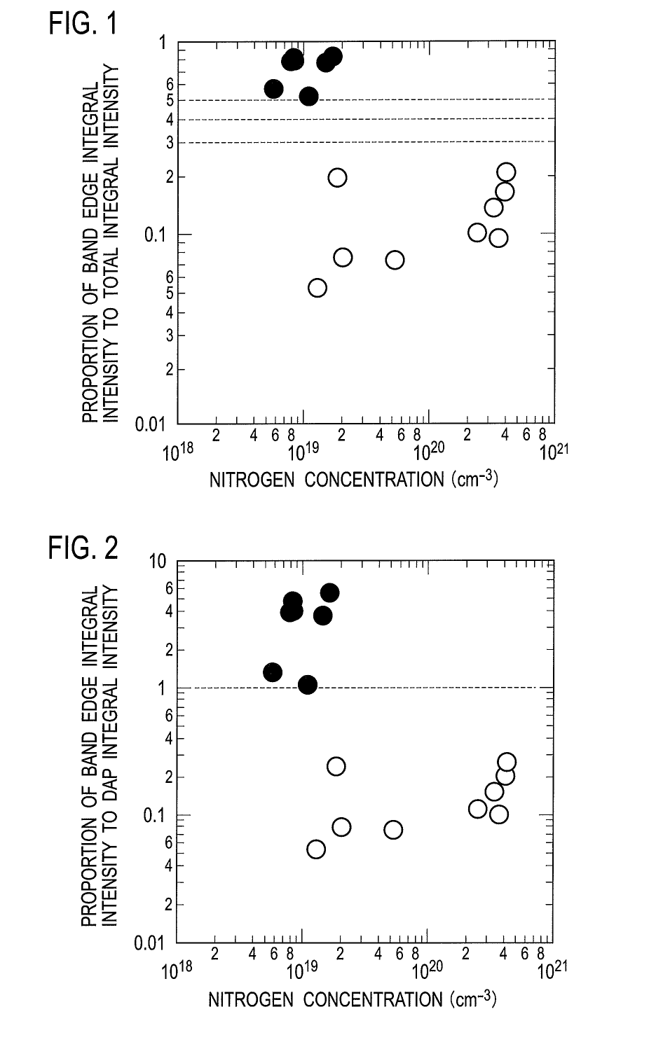

PL measurements are performed on the MgZnO and the ZnO with varied nitrogen concentrations, and the proportion A/B, that is, the proportion of the band edge integral intensity to the total integral intensity (the proportion is represented by the vertical axis) is calculated. The calculated results are plotted on the graph of FIG. 1. FIG. 2 shows a graph of the proportion A/C, that is, the proportion of the band edge integral intensity to the DAP integral intensity (the proportion is represented by the vertical axis). In FIGS. 1 and 2, the horizontal axis represents the concentration of the doped nitrogen (cm⁻³), and the range of the nitrogen concentration is from 1×10¹⁸ cm⁻³ to 1×10²¹ cm⁻³, inclusive.

To calculate A from the data shown in FIGS. 1 and 2, the fitting by Gaussian curves were performed. For comparative purposes, similar calculations were performed for the PL measurement of the nitrogen-doped ZnO. The proportion of the band edge integral intensity to the total integral intensity and the proportion of the band edge integral intensity to the DAP integral intensity were calculated and plotted on the graphs of FIGS. 1 and 2. The white dots (∘) represent the data on the nitrogen-doped ZnO whereas the black dots (•) represent the data on the nitrogen-doped MgZnO.

FIG. 1 shows that concerning the proportion of the band edge integral intensity to the total integral intensity, the data on the nitrogen-doped MgZnO and the data on the nitrogen-doped ZnO are separated from each other with the value range from 0.3 to 0.5 as the border therebetween. So, the border may be set at 0.3 or larger as a loose condition, may be set at 0.4 or larger as a less loose condition, and should be set at 0.5 or larger as a strict condition.

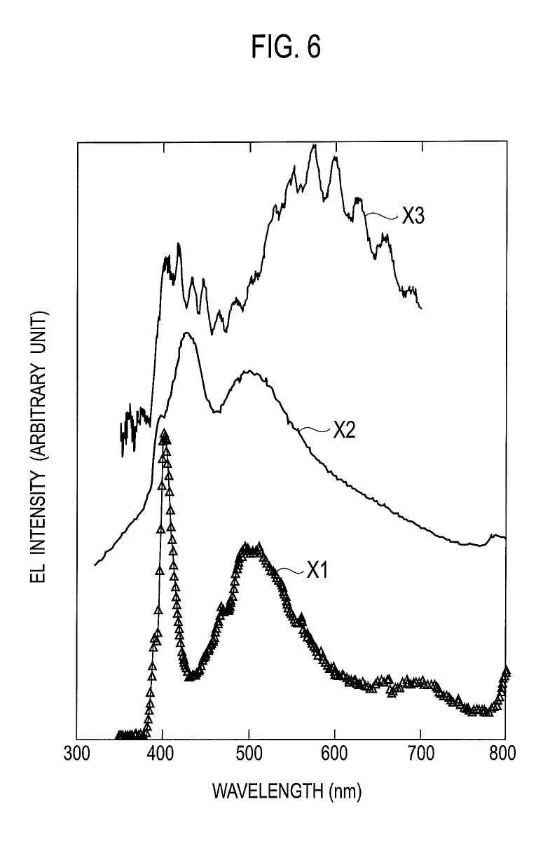

FIG. 2 shows that the proportion of the band edge integral intensity to the DAP integral intensity has only to be set at 1 or larger. Such setting is equivalent to the condition of a 0.5 or larger proportion of the band edge integral intensity to the total integral intensity in FIG. 1. Light emission devices such as ones shown in FIG. 16 were formed each with a p-type layer having the same condition as that of the nitrogen-doped MgZnO used to take data of the black dots (•) shown in FIGS. 1 and 2. The luminescence states of the light emission devices were measured. The measurement results are shown in FIG. 6.

X1 shown in FIG. 6 is a spectrum measured using the nitrogen-doped MgZnO of the present invention. X2 (cited from Non-patent Document 1) and X3 (cited from Non-patent Document 2) are spectra measured using conventional, nitrogen-doped MgZnO. X1 shows sufficiently strong luminescence of light having ultraviolet wavelengths. In contrast, X2 and X3 of the conventional configurations show insufficient luminescence of light having ultraviolet wavelengths, which is not noticeable in the overall spectrum distribution. As has been described thus far, if the nitrogen-doped MgZnO is formed so that the proportion of the band edge integral intensity to the total integral intensity or the proportion of the band edge integral intensity to the DAP integral intensity can satisfy the above-mentioned conditions, the self-compensation effect can be particularly reduced and nitrogen can be activated. What can be obtained consequently is a MgZnO thin film or a MgZnO laminate of a crystal quality that is high enough to make the thin film and the laminate usable as a p-type MgZnO.

As has been described above, the laminate described in FIG. 17(a) was fabricated and was subjected to a PL measurement to obtain the data shown in FIGS. 1 and 2. Now, a method of manufacturing the laminate shown in FIG. 17(a) will be described. The +C plane of the ZnO substrate 1 is etched with hydrochloric acid, then is washed with pure water, and then is dried with dry nitrogen. Subsequently, the resultant ZnO substrate 1 is set in a substrate holder, and is placed in an MBE apparatus through a load lock. The ZnO substrate 1 is then heated at 900° C. for 30 minutes in a vacuum of approximately 1×10⁻⁷ Pa. Then, the temperature of the substrate is lowered down to, for example, 800° C., and NO gas and O₂ gas are supplied to a plasma tube to produce plasma. Mg molecular beams and Zn molecular beams that have been adjusted so as to have desired compositions are casted to form the nitrogen-added MgZnO layer 2. As will be described later, the temperature 800° C., which satisfies the condition requiring 750° C. or higher, is necessary for flattening the surface of the ZnO-based semiconductor. Flattening the surface, impurities such as Si and the like can be removed and high-purity MgZnO can be fabricated.

For conversion into p-type, it is necessary to reduce the self-compensation effect and, in addition to prevent the impurities such as Si serving as the donor from being taken into the MgZnO film. In the fabrication of a MgZnO thin film, a radical generator is used as an apparatus to supply a gas element when oxygen, which is a gas element, is supplied, or when nitrogen, which is a gas element, is doped as an acceptor.

A radical generator (radical cell) includes a hollow discharge tube, a high-frequency coil wound around the outer circumference of the discharge tube, and the like. When a high-frequency voltage is applied to the high-frequency coil, the gas introduced into the discharge tube is turned to plasma and is discharged.

The plasma particles are, however, high-energy particles, so that sputtering phenomenon is caused by the plasma particles. The inner wall of the discharge tube is always sputtered by the plasma particles, and the atoms forming the discharge tube are struck out and mixed into the plasma particles.

In the case of an oxide such as the MgZnO thin film, because the gas component is oxygen, the material often used for the discharge tube in the radical cell is not a material that will be decayed by the oxidation, such as pBN, but is quartz. Quartz is used because, for the time being, it is not easy to obtain a highly insulating material that is as highly pure as quarts. Even in the case of quartz, however, the sputtering by the plasma particles flies Si, Al, B, and the like, which form parts of the discharge tube.

In particular, the amount of flying Si, which is one of the elements included in quartz, is large. The flying Si is supplied directly onto the surface of a growth substrate from a discharging opening of the discharge tube together with the raw-material gas, and is taken into the MgZnO thin film. It is easy to imagine that the Si thus taken into MgZnO occupies the site of Zn. The Si thus occupying the Zn site functions as a donor, and makes it more difficult to achieve the conversion into p-type.

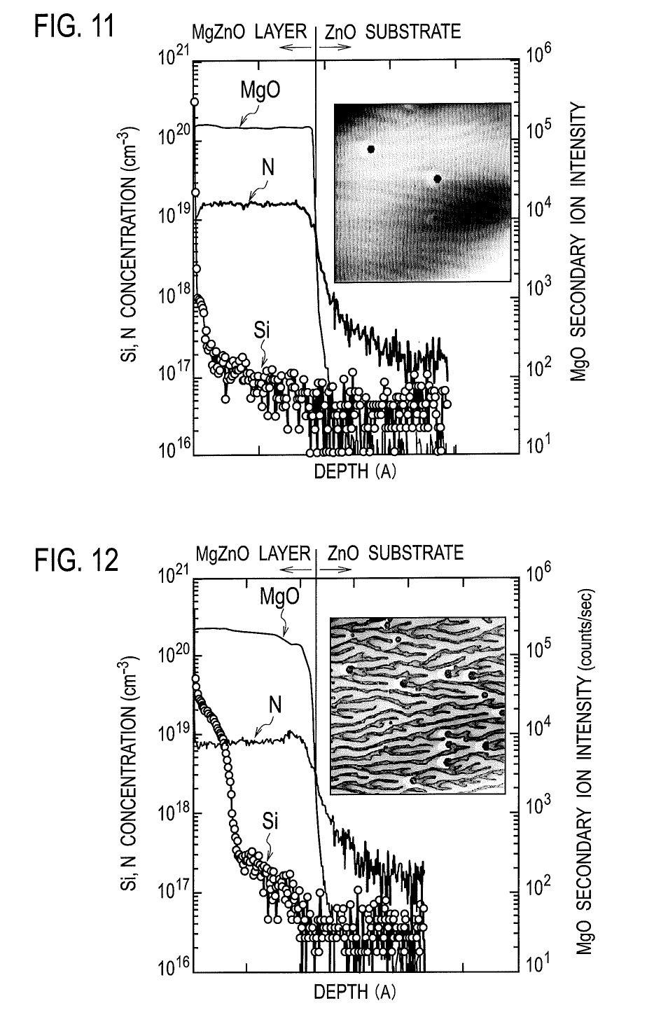

As a solution to this problem, the inventors have found that even if the ZnO-based thin film is formed by crystal growth using a radical cell or the like, a flatter surface of the ZnO-based thin film helps to exclude unintended impurities such as Si. Japanese Patent Application No. 2007-221198, which has been already filed, describes the finding. FIGS. 11 and 12, which are part of the description of Japanese Patent Application No. 2007-221198, show that the surface flatness makes a difference in the mixing of impurities such as Si. Note that, the term ZnO-based in ZnO-based thin film or in ZnO-based semiconductor layer refers to the fact that the material is a mixed crystal material having ZnO as a base and substituting either a IIA-group substance or a IIB-group substance for a part of Zn, or substituting a VIB-group substance for a part of O, or including the combination of both. Here, a MgZnO thin film will be taken as an example.

In particular, Si is one of the elements included in the discharge tube of the radical cell, and is the substance that is mixed in the most. So, Si is taken as an example for the following description. FIGS. 11 and 12 show the association between the surface flatness of the Mg_{X}Zn_{1-X}O thin film (0<X<1) and the concentration of the mixed-in Si. To investigate the association, a nitrogen-doped MgZnO layer 2 was formed on a ZnO substrate 1, as FIG. 17(a) shows, by epitaxial growth performed in an MBE (molecular beam epitaxy) apparatus having a radical cell. The images superposed on the graphs in FIGS. 11 and 12 were obtained by scanning a 20-μm square area of the surface of the nitrogen-doped MgZnO layer 2 by use of an atomic force microscope (AFM). In addition, the silicon concentration and the nitrogen concentration in the MgZnO layer 2 were measured by the secondary ion mass spectroscopy (SIMS).

In each of FIGS. 11 and 12, the vertical axis on the left-hand side represents either the Si concentration or the N concentration whereas the vertical axis on the right-hand side represents the secondary ion intensity of MgO. The images superposed on the graphs represent the surface states of the MgZnO layer 2. The region where the secondary ion intensity of MgO appears corresponds to the MgZnO layer 2 whereas the region where the secondary ion intensity of MgO is almost as low as zero corresponds to the ZnO substrate.

The images superposed in the graphs show that the surface flatness of the MgZnO thin film is better in FIG. 11. The concentration of Si mixed in the thin film is higher in FIG. 12, whose MgZnO thin film has a less flat surface (a coarser surface).

As shown above, the mixing of impurities such as Si depends on the surface flatness of the MgZnO thin film. Next, description will be given below as to the fact that the flatness of the MgZnO thin film formed on the ZnO substrate 1 depends on the off angle formed between the direction of the normal line to the crystal-growth-side surface of the ZnO substrate 1 and the c-axis, which is one of the crystal axes of the substrate.

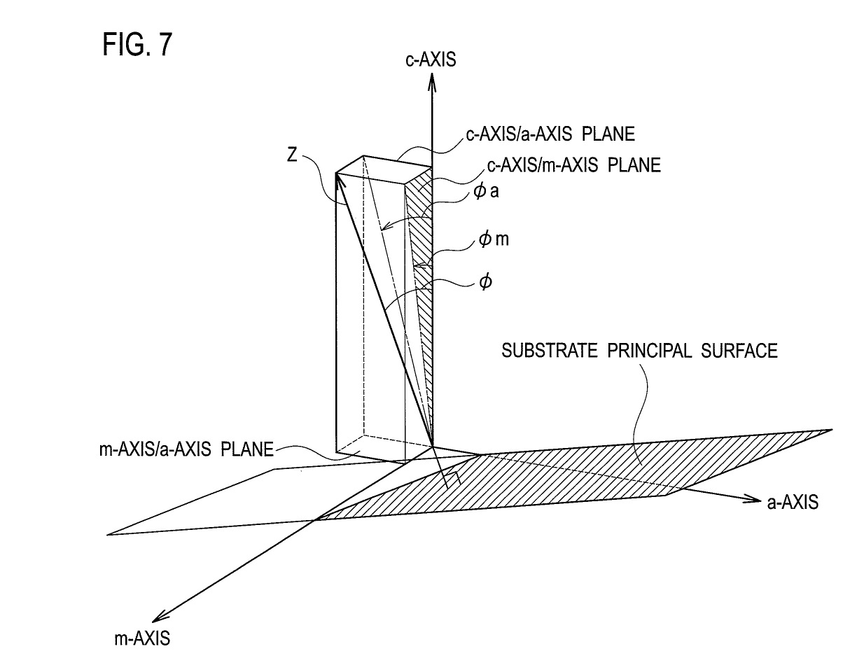

Like GaN, ZnO-based compounds have a hexagonal crystal structure known as Wurtzite. The terms such as the C plane and the a-axis can be expressed by so-called Miller indices. For example, the C plane is expressed as (0001) plane. If a MgZnO thin film is formed on a ZnO substrate by crystal growth, the direction of the normal line to the crystal-growth-side principal surface of the ZnO substrate may coincide with the c-axis of the crystal axes of the substrate. Otherwise, the normal line Z to the principal surface of the substrate is usually inclined as shown in FIG. 7. For example, the normal line Z is inclined from the c-axis of the crystal axes of the substrate at an angle Φ. The projection axis, which is obtained by projecting the normal line Z onto the c-axis/m-axis plane within the Cartesian coordinate system of c-axis, m-axis, and a-axis of the crystal axes of the substrate, is inclined towards the m-axis at an angle Φₘ. The projection axis obtained by projecting the normal line Z onto the c-axis/a-axis plane is inclined towards the a-axis at an angle Φₐ.

Now, suppose a case where the normal line Z to the principal surface of the substrate exists on the c-axis/m-axis plane of the crystal axes of the substrate. When a ZnO-based thin film is made to grow on a ZnO-based material layer, the growth is usually performed on the C plane, that is, the (0001) plane. If a C-plane just substrate is used, the direction of the normal line Z to the wafer's principal surface coincides with the c-axis direction. It is a well-known fact that even if a ZnO-based thin film is made to grow on a C-plane just MgZnO substrate, no improvement can be achieved in the flatness of the film. In addition, in a bulk crystal, the direction of the normal line to the wafer's principal surface does not coincide with the c-axis direction unless a cleavage plane that the crystal has is used. In addition, the use of only the C-plane just substrate results in lower productivity.

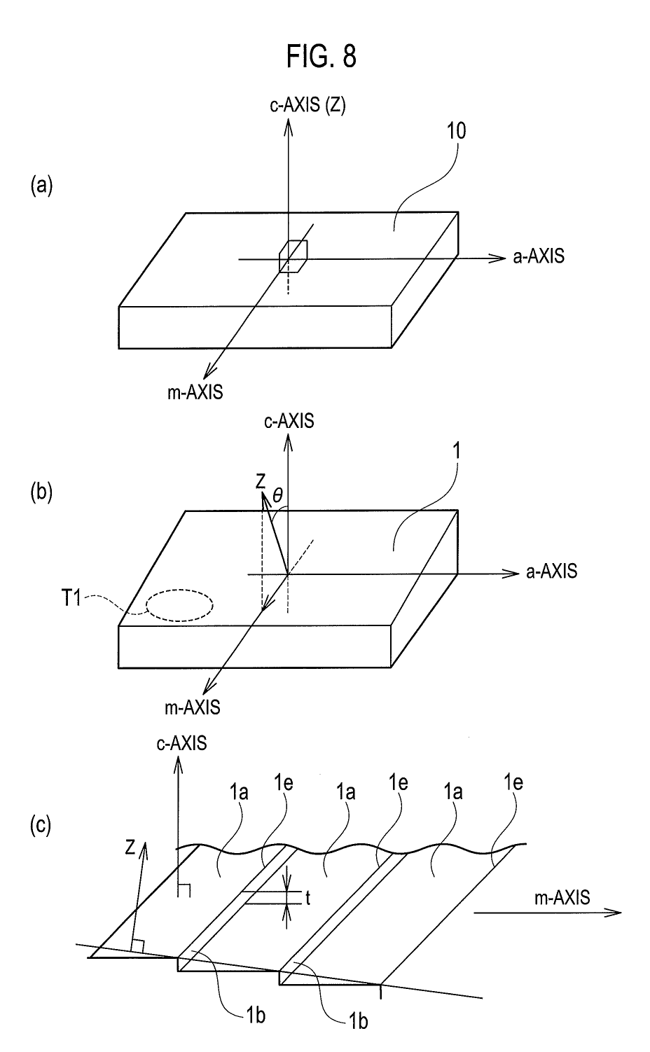

Accordingly, the direction of the normal line to the principal surface of a MgZnO substrate 10 (wafer) is made not to coincide with the c-axis direction. That is, the direction of the normal line Z is inclined from the c-axis of the principal surface of the wafer within the c-axis/m-axis plane, so that an off angle is formed between the direction of the normal line Z and the c-axis. As FIG. 8(b) shows, if the normal line Z to the principal surface of the substrate is inclined from the c-axis towards only the m-axis by θ degrees, for example, terrace surfaces 1a and step surfaces 1b are formed as shown in FIG. 8(c), which is an enlarged view of a surface portion (e.g., of an area T1) of the substrate 10. Each of the terrace surfaces 1a is a flat surface. Each of the step surfaces 1b is formed at a portion where there is a level difference portion formed by the inclination. The step surfaces 1b are arranged equidistantly and regularly.

Note that each terrace surface 1a corresponds to the C plane (0001) whereas each step surface 1b corresponds to the M plane (10-10). As FIG. 8(c) shows, the step surfaces 1b thus formed are arranged in the m-axis direction at regular intervals with the widths of the terrace surfaces 1a maintained equal to each other. As FIG. 8(c) shows, the c-axis, which is perpendicular to the terrace surfaces 1a, is inclined from the Z axis by θ°. Step lines 1e, which are the step edges of the step surfaces 1b, are arranged in parallel with each other at intervals each equal to the width of the terrace surface 1a, while maintaining a perpendicular relationship with the m-axis direction.

In this way, if the step surfaces are formed as surfaces corresponding to the M planes, a ZnO-based semiconductor layer formed by crystal growth on a principal surface can be made as a flat film. Although level-difference portions are formed in the principal surface by the step surfaces 1b, each of the flying atoms that come to these level-difference portions is bonded to the two surfaces, that is, one of the terrace surfaces 1a and a corresponding one of the step surfaces 1b. Accordingly, such atoms can be bonded more strongly than the flying atoms that come to the terrace surfaces 1a. Consequently, the flying atoms can be trapped stably by the level-difference portions.

In a surface diffusion process, the flying atoms are diffused within each terrace. Such atoms are trapped at the level-difference portions where the bonding force is stronger or at kink positions that are formed in the level-difference portions. The trapped atoms are taken into the crystal. The kind of crystal growth that progresses in this way is known as a lateral growth, and is a stable growth. Accordingly, if a ZnO-based semiconductor layer is laminated on a substrate with the normal line to the principal surface of the substrate inclined at least in the m-axis direction, the crystal of the ZnO-based semiconductor layer grow around the step surfaces 1b. Consequently, a flat film can be formed.

To put it differently, what are necessary for the fabrication of a flat film is the step lines 1e which are arranged regularly in the m-axis direction and which have a perpendicular relationship with the m-axis direction. In contrast, if the intervals and the lines of the step lines 1e are improper, the lateral growth described above cannot progress. Consequently, no flat film can be fabricated.

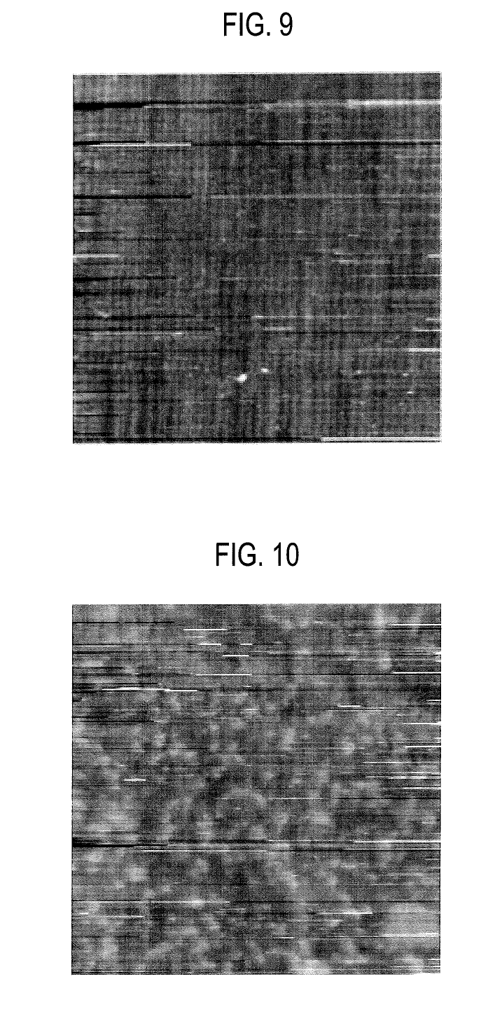

If the inclination angle (off angle) θ shown in FIG. 8(b) is too large, a step height t of each step surface 1b sometimes becomes too high. This prevents the crystal from growing flatly. So, the off angle in the m-axis direction has to be restricted within a certain angle range. FIGS. 9 and 10 show that the flatness of a growing film varies depending upon the inclination angle in the m-axis direction. FIG. 9 is of a case where the inclination angle θ is 1.5° and where a ZnO-based semiconductor is made to grow on a principal surface of a Mg_{X}Zn_{1-X}O substrate having this off angle. FIG. 10 is of a case where the inclination angle θ is 3.5° and where a ZnO-based semiconductor is made to grow on a principal surface of a Mg_{X}Zn_{1-X}O substrate having this off angle. FIGS. 9 and 10 show images obtained by scanning a 1-μm square area by use of an AFM after the crystal growth. The image of FIG. 9 shows that the widths of the steps are arranged regularly and that the film thus formed is fine. The image of FIG. 10 shows that irregularities are found from place to place and thus the flatness is lost. Accordingly, the inclination angle θ is preferably larger than 0° but is not larger than 3° (0<θ≦3). In this way, the mixing of donor impurities such as Si can be avoided.

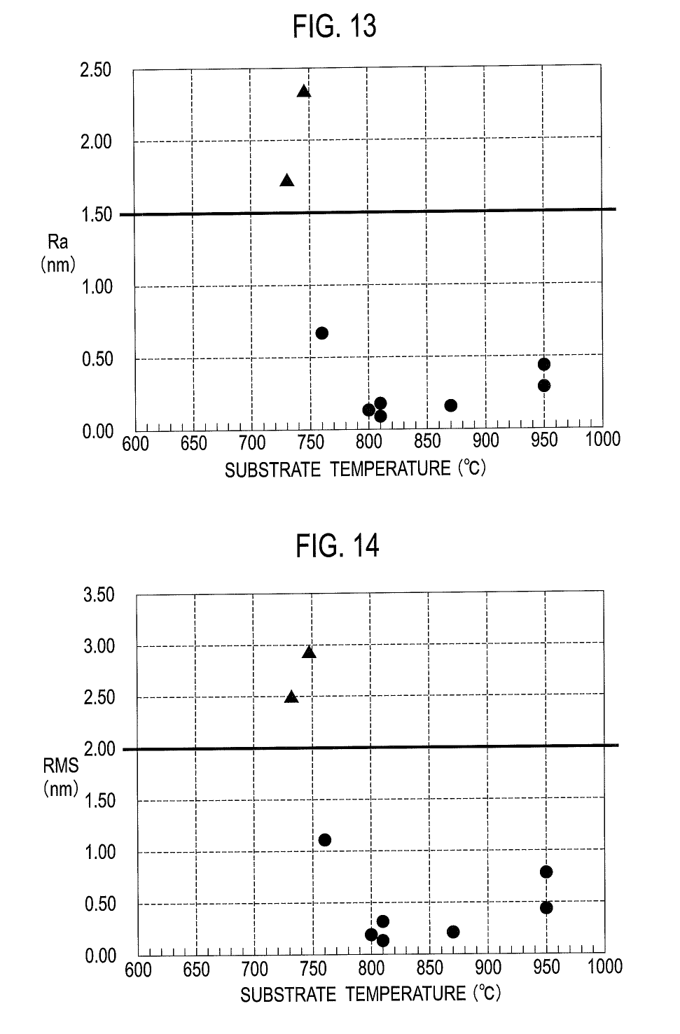

The flatness of a MgZnO film depends also on the growth temperature. Japanese Patent Application No. 2007-27182, which has been already filed, describes in detail the growth-temperature condition. The points will be described again below. ZnO thin films were formed on MgZnO substrates by crystal growth, and the irregularities in the surface of each ZnO thin film were measured. The crystal growth temperature of the ZnO thin film was changed in a fine pitch, and the flatness of the ZnO surface at each temperature was quantified. The graphs of FIGS. 13 and 14 show the results. The vertical axis Ra (the unit is nm) of FIG. 13 represents the arithmetic mean roughness of the film surface. The arithmetic mean roughness Ra is calculated from a roughness curve.

To obtain the roughness curve, the irregularities formed in the film surface and observed as shown in the superposed images of FIGS. 11 and 12 are measured at predetermined sampling points. Then, the sizes of the irregularities are shown together with the average value of these irregularities. A reference length 1 is extracted from the roughness curve towards the average line. The absolute values of the deviations from the average line of the extracted portions to the measured curve are summed up and averaged out. The arithmetic mean roughness Ra is expressed as Ra=(1/1)×∫|f(x)|dx (integral interval is from 0 to 1). A stable result can be obtained in this way because the influence that an error exerts on the measured value can be significantly reduced. The parameters of surface roughness such as the arithmetic mean roughness Ra, root mean square roughness RMS to be described later, and the like are defined by JIS standards. The inventors employ these parameters.

In FIG. 13, the vertical axis represents the arithmetic mean roughness Ra calculated in the above-described way and the horizontal axis represents the temperature of the substrate. The black triangles (▴) in FIG. 13 represent the data obtained at substrate temperatures under 750° C. The black circles (•) represent the data obtained at substrate temperatures of 750° C. or higher. As can be seen from FIG. 13, if the substrate temperature reaches 750° C. and rises even higher, the flatness of the surface improves drastically. The border value of the arithmetic mean roughness Ra is approximately 1.5 nm if the arithmetic mean roughness Ra is taken loosely, and is approximately 1.0 nm if the arithmetic mean roughness Ra is taken strictly.

FIG. 14 shows the root mean square roughness RMS of the film surface calculated from the same measured data as used in the case of FIG. 13. The root mean square roughness RMS is the square root of the average value for the sum of the squared deviations from the average line of the roughness curve to the measured curve.

With the reference length 1 used in the calculation of the arithmetic mean roughness Ra, the root mean square roughness RMS is expressed as

RMS={(1/1)×∫(f(x))²dx}^{1/2}(integral interval is from 0 to 1)

In FIG. 14, the vertical axis represents the root mean square roughness RMS and the horizontal axis represents the temperature of the substrate. The black triangles (▴) represent the data obtained at substrate temperatures under 750° C. The black circles (•) represent the data obtained at substrate temperatures of 750° C. or higher. Like FIG. 13, if the substrate temperature reaches 750° C. and rises even higher, the flatness of the surface improves drastically. The border value of the root mean square roughness RMS is approximately 2.0 nm if the root mean square roughness RMS is taken loosely, and is approximately 1.5 nm if the root mean square roughness RMS is taken strictly.

Accordingly, when a ZnO-based thin film is made to grow on a MgZnO substrate, a flatter film can be obtained by an epitaxial growth process performed with the substrate temperature kept at 750° C. or higher. In addition, when a layer of a ZnO-based thin film such as a MgZnO film is laminated repeatedly on top of a MgZnO substrate, keeping the substrate temperature at 750° C. or higher allows all the layers of films to be laminated flatly until the uppermost layer, and also prevents mixing of donor impurities such as Si.

Description of the device shown in FIG. 16 has already been given above. A flat laminate can be formed by laminating a ZnO-based semiconductor layer on a ZnO substrate 12 having the above-mentioned off angle. Specifically, the crystal-growth surface of the ZnO substrate 12 is used as the principal surface having +C plane, and the direction of the normal line to the principal surface is inclined a little from the c-axis in the m-axis direction. An undoped ZnO layer 13 and a nitrogen-doped p-type MgZnO layer 14 are formed in this order on the ZnO substrate 12 by crystal growth. The nitrogen-doped MgZnO layer 14 corresponds to the ZnO-based semiconductor of the present invention. An even better flatness of the surface is obtained by keeping the growth temperature at approximately 800° C. Needless to say, the device structure is not limited to this. The ZnO-based laminate shown in FIG. 16 may be formed as a laminate of a MgZnO substrate, an undoped ZnO layer, and a nitrogen-doped MgZnO layer. Alternatively, active layers may be provided additionally, and these active layers, and layers of MgZnO and of ZnO may be laminated alternately to produce a multiple quantum well (MQW) structure.

1. A ZnO-based semiconductor including a Mg_{X}Zn_{1-X}O (0<X<1) crystalline material doped with nitrogen,
wherein, in a spectrum distribution curve obtained by a photoluminescence measurement performed on the ZnO-based semiconductor at an absolute temperature of 12 Kelvin, a peak intensity of the distribution curve obtained at 3.3 eV or larger is stronger than a peak intensity of the distribution curve obtained at 2.7 eV or smaller.

2. A ZnO-based semiconductor including a Mg_{X}Zn_{1-X}O (0<X<1) crystalline material doped with nitrogen,
wherein, in a spectrum distribution curve obtained by a photoluminescence measurement performed on the ZnO-based semiconductor at an absolute temperature of 12 Kelvin, an integral intensity of the distribution curve obtained at 3.3 eV or larger is stronger than an integral intensity of the distribution curve obtained at 2.7 eV or smaller.

3. A ZnO-based semiconductor including a Mg_{X}Zn_{1-X}O (0<X<1) crystalline material doped with nitrogen,
wherein, in a spectrum distribution curve obtained by a photoluminescence measurement performed on the ZnO-based semiconductor at an absolute temperature of 12 Kelvin, when an integral intensity of the distribution curve obtained at 3.3 eV or larger is denoted by A and an integral intensity of the distribution curve obtained at 2.7 eV or larger is denoted by B, (A/B)≧0.3 is satisfied.

4. The ZnO-based semiconductor according to claim 3, wherein the (A/B) is equal to or larger than 0.4.

5. A ZnO-based semiconductor including a Mg_{X}Zn_{1-X}O (0<X<1) crystalline material doped with nitrogen,
wherein, in a spectrum distribution curve obtained by a photoluminescence measurement performed on the ZnO-based semiconductor at an absolute temperature of 12 Kelvin, when an integral intensity of the distribution curve obtained at 3.3 eV or larger is denoted by A and an integral intensity of the distribution curve obtained at 2.7 eV or larger is denoted by B, {A/(B−A)}≧1 is satisfied.

6. The ZnO-based semiconductor according to any one of claims 3 to 5, wherein to calculate the integral intensity A, the distribution curve at 3.3 eV or larger is approximated by a Gaussian curve, and then the Gaussian curve is integrated.

7. The ZnO-based semiconductor according to claim 6, wherein, if a plurality of luminescence peaks exist in the distribution curve at 3.3 eV or larger, the luminescence peaks are approximated respectively by Gaussian curves.

8. The ZnO-based semiconductor according to any one of claims 1 to 5, wherein a concentration of the doped nitrogen is equal to or higher than 1×10¹⁸ cm⁻³.

9. The ZnO-based semiconductor according to any one of claims 1 to 5, wherein the crystalline material is a laminate formed by laminating a plurality of layers of Mg_{X}Zn_{1-X}O (0≦Xn<1) with Mg composition ratios that are different from one another, and
at least one of the MgZnO films is doped with nitrogen at a concentration that is equal to or higher than 1×10¹⁸ cm⁻³.

10. The ZnO-based semiconductor according to any one of claims 1 to 5, wherein the crystalline material includes a MgZnO substrate in which a principal surface on a crystal-growth-direction side has a C plane, and a Mg_{Y}Zn_{1-Y}O (0<Y<1) film which is formed on the MgZnO substrate, and
a projection axis, obtained by projecting a normal line to the principal surface onto a m-axis/c-axis plane of substrate crystal axes, is inclined in the m-axis direction within a range of 3°.

11. The ZnO-based semiconductor according to any one of claims 1 to 5, wherein the crystalline material is formed by a crystal growth process performed at a growth temperature of 750° C. or higher.

12. A ZnO-based semiconductor device comprising the ZnO-based semiconductor according to any one of claims 1 to 5.
